(19) United States
(12) Patent Application Publication
(10) Pub. No.: US 2026/0363026 A1
(43) Pub. Date: Nov. 12, 2026

(54) METHOD FOR TESTING WAFER MOUNTING TAPE AND APPARATUS FOR TESTING WAFER MOUNTING TAPE

(71) Applicant: SAMSUNG ELECTRONICS CO., LTD., Suwon-si (KR)

(72) Inventors: Dae-Woong CHOI, Suwon-si (KR); Yongwon KIM, Suwon-si (KR); Jonghwan BAE, Suwon-si (KR); Jun Seong HWANG, Suwon-si (KR)

(73) Assignee: SAMSUNG ELECTRONICS CO., LTD., Suwon-si (KR)

(21) Appl. No.: 19/410,762

(22) Filed: Dec. 5, 2025

(30) Foreign Application Priority Data
May 7, 2025 (KR) 10-2025-0059363

(51) Int. Cl. H10P 74/20; H10P 72/00; H10P 74/00

(52) U.S. Cl. CPC H10P 74/203; H10P 72/0618; H10P 74/27

(57) ABSTRACT

A method for testing wafer mounting tape including attaching a wafer mounting tape to a lower surface of a ring frame, the ring frame having a wafer attachment region inside thereof, attaching a wafer to the wafer mounting tape within the attachment region, jetting a testing gas on the wafer mounting tape and the wafer using a first testing device, obtaining a testing image of the ring frame, the wafer mounting tape, and the wafer using a second testing device, comparing the testing image to a reference image, and determining a failure of the wafer mounting tape based on an error between the testing image and the reference image.

### CROSS-REFERENCE TO RELATED APPLICATIONS

This U.S. non-provisional patent application claims priority under 35 U.S.C. §119 to Korean Patent Application No. 10-2025-0059363, filed on May 07, 2025, in the Korean Intellectual Property Office, the entire contents of which are hereby incorporated by reference.

### BACKGROUND

The present disclosure relates to a method for testing a wafer mounting tape and an apparatus for testing the wafer mounting tape.

Within the substrate processing process, a ring frame is used for easy handling of a substrate such as a wafer or a semiconductor die. The substrate may be fixed within the inner attachment region of the ring frame using a mounting tape connected to the ring frame.

Currently, to satisfy the increasing demand for semiconductor devices, manufactures are producing larger substrates (e.g., semiconductor wafers) and/or increasing the yield of semiconductor dies (i.e., “chips”) that can be produced by processing a substrate. Therefore, a size of the ring frame and a size of the mounting tape used for processing the semiconductor devices are also increasing. As a result, good adhesion between the substrate or the semiconductor die and the mounting tape becomes increasingly difficult, and improvements are needed.

### SUMMARY

One or more embodiments of the present disclosure may provide a method for testing a wafer mounting tape and an apparatus for testing the wafer mounting tape, which prevent a failure determination from being missed.

One or more embodiments of the present disclosure may provide a method for testing a wafer mounting tape and an apparatus for testing the wafer mounting tape, which capable of precise test is provided.

One or more embodiments of the present disclosure may provide a method for testing a wafer mounting tape and an apparatus for testing the wafer mounting tape, which are easy to continuously test a plurality of test objects.

One or more embodiments of the present disclosure may provide a method for testing a wafer mounting tape including: attaching a wafer mounting tape to a lower surface of a ring frame having a wafer attachment region inside; attaching a wafer to the wafer mounting tape within the attachment region; jetting a testing gas on the wafer mounting tape and the wafer using a first testing device; obtaining a testing image of the ring frame, the wafer mounting tape, and the wafer using a second testing device; comparing the testing image to a reference image; and determining a failure of the wafer mounting tape based on an error between the testing image and the reference image.

One or more embodiments of the present disclosure may provide an apparatus for testing a wafer mounting tape may include: a body having an inner space configured to receive one or more test objects; a mounting slot in the inner space; a first testing device in the inner space and above the one or more test objects, wherein the first testing device is configured to expand a breakage portion of a wafer mounting tape of the one or more test objects by jetting a testing gas toward the one or more test objects; and a second testing device in the inner space and above the one or more test objects, wherein the second testing device is configured to monitor a planar shape of the one or more test objects

One or more embodiments of the present disclosure may provide a method for testing a wafer mounting tape including: obtaining a reference image of a reference wafer mounting tape using a first testing device; jetting a testing gas toward a wafer mounting tape using a second testing device, wherein a breakage portion formed in the wafer mounting tape is configured to expand due to the jetting the testing gas; obtaining a testing image of the wafer mounting tape using the first testing device; comparing the testing image to the reference image; and determining a failure of the wafer mounting tape based on an error between the testing image and the reference image, wherein the breakage portion is recorded in the testing image, and wherein the breakage portion is configured to cause the error between the testing image and the reference image.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is a plan view illustrating a test object of a testing apparatus for wafer mounting tape according to one or more embodiments of the present disclosure.

FIG. 2 is a cross-sectional view illustrating a test object of a testing apparatus for wafer mounting tape according to one or more embodiments of the present disclosure.

FIG. 3 is a schematic diagram schematically illustrating a substrate processing system including an apparatus for testing a wafer mounting tape according to one or more embodiments of the present disclosure.

FIGS. 4 and 5 are cross-sectional views illustrating an apparatus for testing a wafer mounting tape according to one or more embodiments of the present disclosure.

FIG. 6 is a flowchart for describing a method for testing a wafer mounting tape according to one or more embodiments of the present disclosure.

FIGS. 7A, 8A, 9A, 10A and 11 are cross-sectional views of an apparatus for testing a wafer mounting tape for describing a method for testing the wafer mounting tape according to one or more embodiments of the present disclosure.

FIG. 7B is a plan view of a reference object for describing a method for testing a wafer mounting tape according to one or more embodiments of the present disclosure.

FIG. 7C is a cross-sectional view of a test object for describing a method for testing a wafer mounting tape according to one or more embodiments of the present disclosure.

FIGS. 8B, 9B, and 10B are top views of a test object for describing a method for testing a wafer mounting tape according to one or more embodiments of the present disclosure.

FIGS. 8C, 9C, 9D, and 10C are partial enlarged views of a cross section of a test object for describing a method for testing a wafer mounting tape according to one or more embodiments of the present disclosure.

FIG. 11 is a cross-sectional view of an apparatus for testing a wafer mounting tape for describing a method for testing the wafer mounting tape according to one or more embodiments of the present disclosure.

### DETAILED DESCRIPTION

Example embodiments of the present disclosures will now be described more detail with reference to the accompanying drawings, in which example embodiments are shown.

It will be understood that when an element, component, layer, pattern, structure, region, or so on (hereinafter collectively “element”) of a semiconductor device is referred to as being “over,” “above,” “on,” “below,” “under,” “beneath,” “connected to” or “coupled to” another element of the semiconductor device, it can be directly over, above, on, below, under, beneath, connected or coupled to the other element or an intervening element(s) may be present. In contrast, when an element of a semiconductor device is referred to as being “directly over,” “directly above,” “directly on,” “directly below,” “directly under,” “directly beneath,” “directly connected to” or “directly coupled to” another element of the semiconductor device, there are no intervening elements present.

As used herein, the term “and/or” includes any and all combinations of one or more of the associated listed items. As used herein, expressions such as “at least one of,” when preceding a list of elements, modify the entire list of elements and do not modify the individual elements of the list. For example, the expression, “at least one of a, b and c,” and “at least one of a, b, or c” should be understood as including only a, only b, only c, both a and b, both a and c, both b and c, or all of a, b and c.

It will be also understood that, even if a certain step or operation of manufacturing an apparatus or structure is described later than another step or operation, the step or operation may be performed later than the other step or operation unless the other step or operation is described as being performed after the step or operation.

Various embodiments of the present document and terms used therein are not intended to limit the technical features described in this document to specific embodiments, and should be understood to include various modifications, equivalents, or substitutes of the corresponding embodiments.

In connection with the description of the drawings, similar reference numerals may be used for similar or related components.

The singular form of a noun corresponding to an item may include one or a plurality of the items unless clearly indicated otherwise in a related context.

In addition, the terms “portion”, “part”, “unit”, “module” or “member” may be implemented in hardware or software. Depending on the embodiments, a plurality of “portions”, “parts”, “units”, “modules” or “members” may be implemented as a single element, or a single “portion”, “part”, “unit”, “module” or “member” may include a plurality of elements.

It will be understood that, although the terms “first”, “second”, “third”, “primary”, “secondary”, “tertiary”, etc., may be used herein to describe various elements, but elements are not limited by these terms. These terms are only used to distinguish one element from another element. For example, without departing from the scope of the disclosure, a first element may be termed as a second element, and a second element may be termed as a first element. The term of “and/or” includes a plurality of combinations of relevant items or any one item among a plurality of relevant items.

When an element (e.g., a first element) is referred to as being “(functionally or communicatively) coupled” or “connected” to another element (e.g., a second element), the first element may be connected to the second element, directly (e.g., wired), wirelessly, or through a third element.

In this disclosure, the terms “containing”, “including”, “comprising”, “having”, and the like are used to specify features, numbers, steps, operations, elements, components, or combinations thereof, but do not preclude the presence or addition of one or more of the features, numbers, steps, operations, elements, components, or combinations thereof.

In addition, in the present disclosure, the meaning of “identical” includes cases where properties are similar to each other or similar within a certain range. Furthermore, identical means “substantially identical”. The meaning of substantially identical should be understood to include numerical values within manufacturing error ranges or differences within a range that is insignificant with respect to a reference numerical value as falling within the scope of ‘identical’.

As used herein, the terms “front (or forward)”, “rear (or back, rearward)”, “left”, “right”, “up (or top)”, “down (or bottom)” and the like may be defined with reference to the drawings, and may not be intended to limit the shape and position of each component.

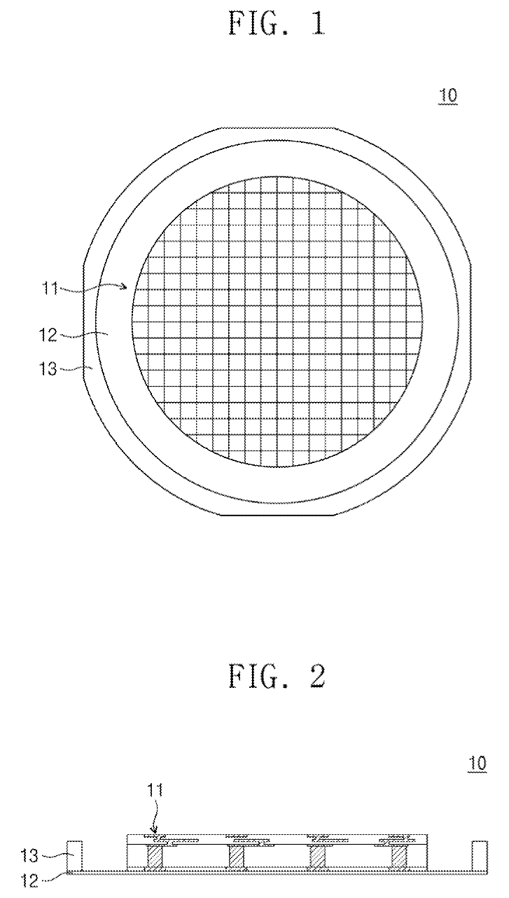

FIG. 1 is a plan view illustrating a test object of a testing apparatus for wafer mounting tape according to one or more embodiments of the present disclosure. FIG. 2 is a cross-sectional view illustrating the test object of a testing apparatus for wafer mounting tape according to one or more embodiments of the present disclosure.

Referring to FIGS. 1 and 2, a testing apparatus for wafer mounting tape according to one or more embodiments of the present disclosure may test the test object 10. The test object 10 may include, for example, a substrate 11, a wafer mounting tape 12, and a ring frame 13. The substrate 11 may comprise, for example, a semiconductor wafer.

Electronic elements such as semiconductor elements may be formed on the substrate 11 in the previous process. For example, the substrate 11 may include a plurality of dies arranged in a matrix form and a scribe lane between the dies. The substrate 11 may include, for example, a semiconductor wafer. Alternatively, the substrate 11 may include a circuit board.

In FIG. 2, only some configurations of the substrate 11 is schematically illustrated, and the substrate 11 of the test object 10 in the present invention is not limited thereto. For example, the substrate 11 may include an integrated circuit formed on a front surface of the substrate 11, a via vertically penetrating the substrate 11, an interconnection layer provided on the front surface of the substrate 11, and pads provided on a rear surface of the substrate 11.

According to one or more embodiments, the substrate 11 may be provided in a cut state by a singulation process. The substrate 11 may be cut into a matrix form according to the arrangement of the dies.

The substrate 11 may be attached to the wafer mounting tape 12. The wafer mounting tape 12 may have a larger area than that of the substrate 11. The substrate 11 may be attached on a central portion of the wafer mounting tape 12. The wafer mounting tape 12 may be made of a material that is stretchable in the horizontal direction.

The ring frame 13 may be connected around of the wafer mounting tape 12 to tightly support the wafer mounting tape 12. For example, the wafer mounting tape 12 may be adhered or connected to a lower surface of the ring frame 13. As the wafer mounting tape 12 is tightly pulled by the ring frame 13, the substrate 11 may be stably adhered to the wafer mounting tape 12. When the substrate 11 is provided in a cut state, as the wafer mounting tape 12 is tightly pulled by the ring frame 13, the positions of the plurality of dies may be fixed, and the dies in a thin plate form may maintain a flat plate form.

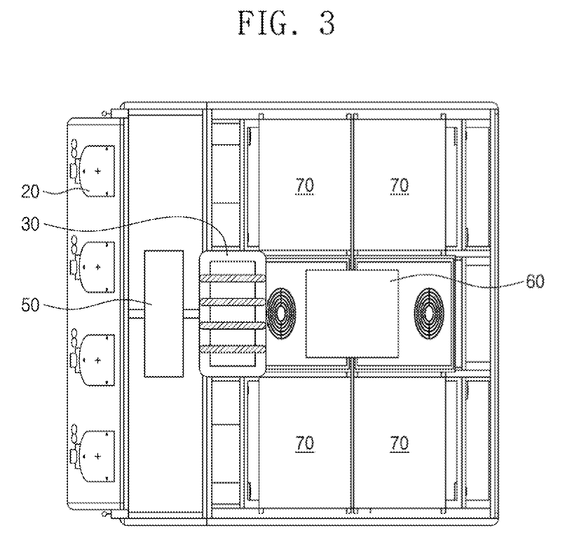

FIG. 3 is a schematic diagram schematically illustrating a substrate processing system including an apparatus for testing a wafer mounting tape according to one or more embodiments of the present disclosure.

Referring to FIG. 3, a wafer cassette 20 may have an inner space that is sealed from an outside to load a plurality of objects. Here, the objects may be a substrate, a wafer, or a ring frame to which the substrate or the wafer is attached. The test object 10 described above with reference to FIGS. 1 and 2 means those among the plurality of objects that are loaded in a wafer mounting tape testing apparatus 30 to test. That is, the “object” and “test object” referred to herein are merely names according to a role of an object in the substrate processing system, and do not refer to different configurations. The wafer mounting tape testing apparatus 30 may be an apparatus for testing the wafer mounting tape.

The wafer cassette 20 may load the objects and move between unit process facilities, and may deliver the objects. For example, the wafer cassette 20 may be a front opening unified pod (FOUP). The wafer cassette 20 transferred to one of the unit process facilities may be loaded on an upper surface of a load port module disposed on one side of the one of the unit process facilities, and may open a cassette door while sealing the inner space of the wafer cassette 20 from the outside. As such, the objects may move between the unit process facilities while avoiding contamination from an external environment.

A first transfer module 50 may grip the objects in the wafer cassette 20, and may load the objects on the wafer mounting tape testing apparatus 30. The first transfer module 50 may be, for example, a vacuum adsorption robot that adsorbs the objects by vacuum pressure. Alternatively, the first transfer module 50 may include an end effector that grips the edges of the objects. The wafer mounting tape testing apparatus 30 may test a failure or misalignment of the object, for example, the test object 10 described with reference to FIGS. 1 and 2, which is placed inside the wafer mounting tape testing apparatus 30. The specific configuration of the wafer mounting tape testing apparatus 30 will be described in more detail later.

Objects determined to be normal in the wafer mounting tape testing apparatus 30 may be put into a substrate processing chamber 70 by a second transfer module 60. The second transfer module 60 may be, for example, a vacuum adsorption robot that adsorbs the objects by vacuum pressure. Alternatively, the second transfer module 60 may include an end effector that grips the edges of the objects. The substrate processing chamber 70 may process the objects while spraying a processing solution on the objects. For example, the processing process for the objects may be a cleaning process for removing impurities such as an adhesive. However, the present invention is not limited thereto, and at least one of various substrate processing processes may be performed as necessary in the substrate processing chamber 70. A plurality of substrate processing chambers 70 may be provided.

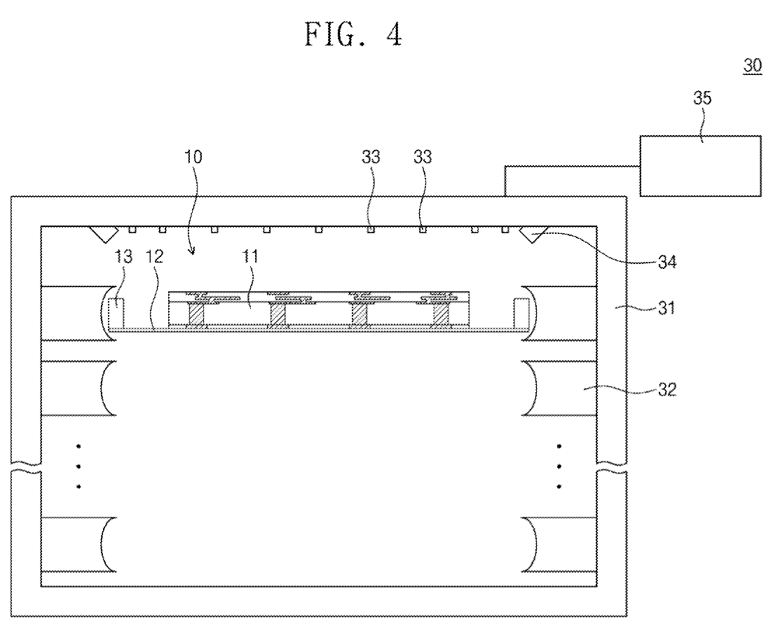

FIG. 4 is a cross-sectional view illustrating an apparatus for testing a wafer mounting tape according to one or more embodiments of the present disclosure.

Referring to FIG. 4, the wafer mounting tape testing apparatus 30 may include a body 31 having an inner space in which objects are loaded. Among the objects on which the process is performed in the substrate processing system, an object inserted into the wafer mounting tape testing apparatus 30 may be a test object on which the testing process is performed by the wafer mounting tape testing apparatus 30. Therefore, it will be referred to below as the test object 10 which is not to be confused with one of the plurality of objects.

The inner space of the body 31 may be sealed from the outside. Accordingly, while the wafer mounting tape testing apparatus 30 is used to test defects of the test object 10, the test object 10 seated in the body 31 may be prevented from being contaminated from an external environment.

The body 31 may include a door or port for loading or unloading the test object 10 in the inner space of the body 31.

A mounting slot 32 may be provided in the body 31. The mounting slot 32 may serve to substantially mount the test object 10 inserted into the body 31. For example, the mounting slot 32 may be provided on an inner wall of the inner space of the body 31, and the mounting slot 32 may grip or support an edge of the test object 10. The mounting slot 32 may be provided in plural. A plurality of the mounting slots 32 may be arranged vertically in the inner space of the body 31. A plurality of test objects 10 may be provided. Each of the mounting slots 32 may have a space to mount one of the test objects 10. The test objects 10 may be arranged and mounted vertically in the inner space of the body 31.

Although FIG. 4 shows that the test object 10 is mounted only on the topmost mounting slot 32 among the mounting slots 32, the present invention is not limited thereto. Depending on a progress of the process in the substrate processing system, the test objects 10 may be mounted or withdrawn in each of the mounting slots 32 of the body 31. That is, the topmost mounting slot 32 of the mounting slots 32 may correspond to a stage for performing a testing process on the topmost test object 10 therein, and the remaining mounting slots 32 may correspond to a storage portion for mounting the test objects 10.

According to an aspect of an example embodiment, with reference to FIGS. 3 and 4, the plurality of mounting slots 32 may be provided in the body 31 of the wafer mounting tape testing apparatus 30 for testing the test objects 10. The plurality of test objects 10 may be loaded in the inner space of the body 31. The wafer mounting tape testing apparatus 30 may test the objects of the substrate processing system, and also, serve as a buffer unit for temporarily storing the objects between a plurality of unit processes of the substrate processing system. For example, the wafer cassette 20 may be moved through a transfer unit of the substrate processing system, and the wafer mounting tape testing apparatus 30 that receives the objects from the wafer cassette 20 may test and store the objects. Thereafter, the objects determined to be normal may be withdrawn from the wafer mounting tape testing apparatus 30 and transferred to the substrate processing chambers 70. Thus, an apparatus for testing and storage of the objects may be provided as one, not separately. That is, the wafer mounting tape testing apparatus 30 may provide the substrate processing system with more simplified process steps.

Referring to FIG. 4, a first testing unit 33 (e.g., a device or apparatus) may be provided in the body 31. The first testing unit 33 may be arranged on the mounting slots 32 in the inner space of the body 31. For example, the first testing unit 33 may be installed at a ceiling portion of the inner space of the body 31. The first testing unit 33 may jet a testing gas toward the test object 10. For example, the first testing unit 33 may jet the testing gas toward the inner space of the body 31, more preferably toward a lower side from the ceiling portion. The testing gas may be jetted from above the test object 10 toward the test object 10. The first testing unit 33 may comprise a gas jetting nozzle disposed on the mounting slots 32 in the inner space of the body 31. The testing gas may comprise an inert gas. For example, the testing gas may comprise nitrogen gas. A plurality of first testing units 33 may be provided. For example, a plurality of gas jetting nozzles may be provided. The first testing units 33 may be located on the test object 10. At least some of the first testing units 33 may be located on a portion of the wafer mounting tape 12 located between the substrate 11 and the ring frame 13 of the test object 10 in a plan view. That is, the at least some of the first testing units 33 may jet the testing gas toward the portion of the wafer mounting tape 12. When there is a breakage portion in the wafer mounting tape 12 of the test object 10, the testing gas jetted by the first testing units 33 may expand the breakage portion. This will be described in more detail later with a method for testing a wafer mounting tape.

A second testing unit 34 (e.g., a device or apparatus) may be provided in the body 31. The second testing unit 34 may be arranged on the mounting slots 32 in the inner space of the body 31. For example, the second testing unit 34 may be installed at the ceiling portion of the inner space of the body 31. The second testing unit 34 may photograph or otherwise monitor the test object 10, and may comprise any suitable image and/or radiation sensing device or apparatus. More preferably, the second testing unit 34 may photograph a planar shape of the test object 10 from above the test object 10. The second testing unit 34 may comprise a vision camera arranged on the mounting slots 32 in the inner space of the body 31. That is, the second testing unit 34 may perform optical photographing on an upper shape of the test object 10. A plurality of second testing units 34 may be provided. The second testing units 34 may be located on the test object 10.

The wafer mounting tape testing apparatus 30 may further include an image processing unit 35 (e.g., at least one or more processors, computers, etc.). The image processing unit 35 may utilize an image photographed by the second testing unit 34 to determine whether the test object 10 is in a state of failure. For example, the image processing unit 35 may compare the testing image collected from the second testing unit 34 with the reference image stored to determine whether the test object 10 is in a state of failure. This will be described in more detail with a method for testing a wafer mounting tape. The image processing unit 35 may be provided outside the body 31. That is, the image processing unit 35 may be provided in a space separate from the body 31, and may be electrically connected to the second testing unit 34 through an electrical wiring or the like. Alternatively, the image processing unit 35 may be installed in the body 31. For example, the image processing unit 35 may be provided on an outer surface of the body 31 or in the inner space of the body 31.

In embodiments below, for convenience of description, detailed description of technical features that merely repeats or overlaps with the description of FIGS. 1-4 may be omitted. However, differences may be described in detail.

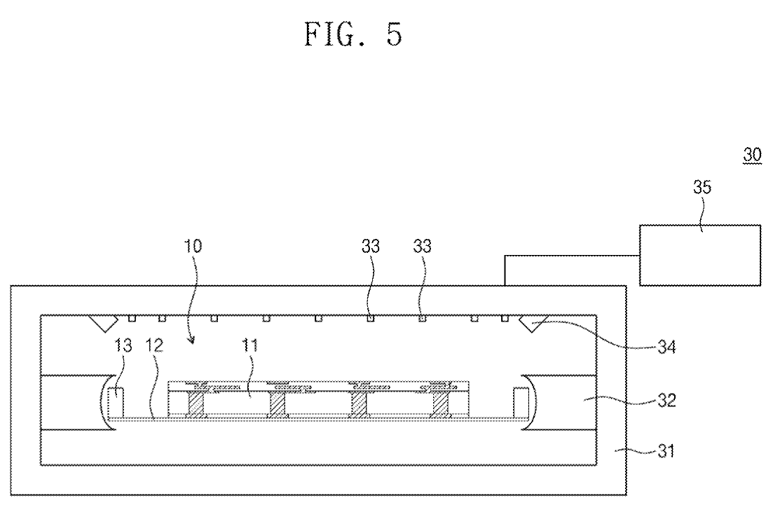

FIG. 5 is a cross-sectional view illustrating an apparatus for testing a wafer mounting tape according to one or more embodiments of the present disclosure.

Although FIG. 4 shows that the wafer mounting tape testing apparatus 30 may include a plurality of mounting slots 32, and the wafer mounting tape testing apparatus 30 may serve as a testing unit for testing the test objects 10 and a buffer unit for storing the test objects 10 together, the present invention is not limited thereto.

Referring to FIG. 5, the wafer mounting tape testing apparatus 30 may include one mounting slot 32. That is, the mounting slot 32 of the wafer mounting tape testing apparatus 30 may correspond to a stage for performing a testing process on the test object 10. Accordingly, the wafer mounting tape testing apparatus 30 may be small in size. In this case, a buffer unit for storing the objects of the process may be separately provided in the substrate processing system of FIG. 3.

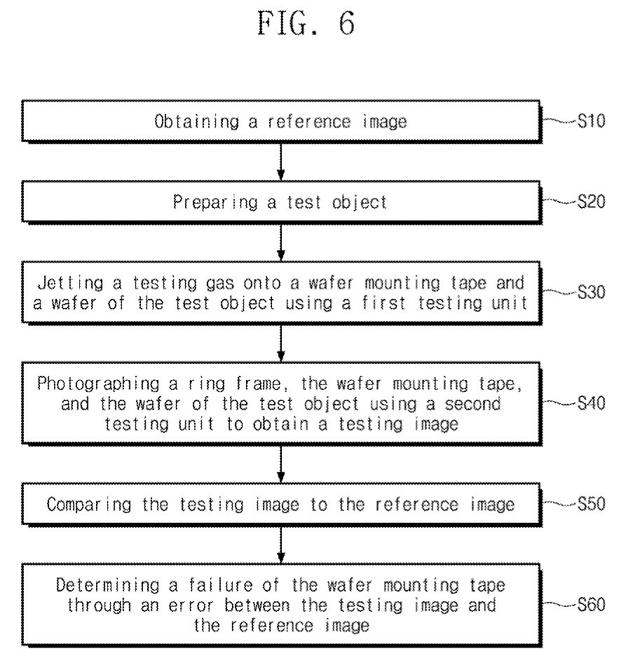

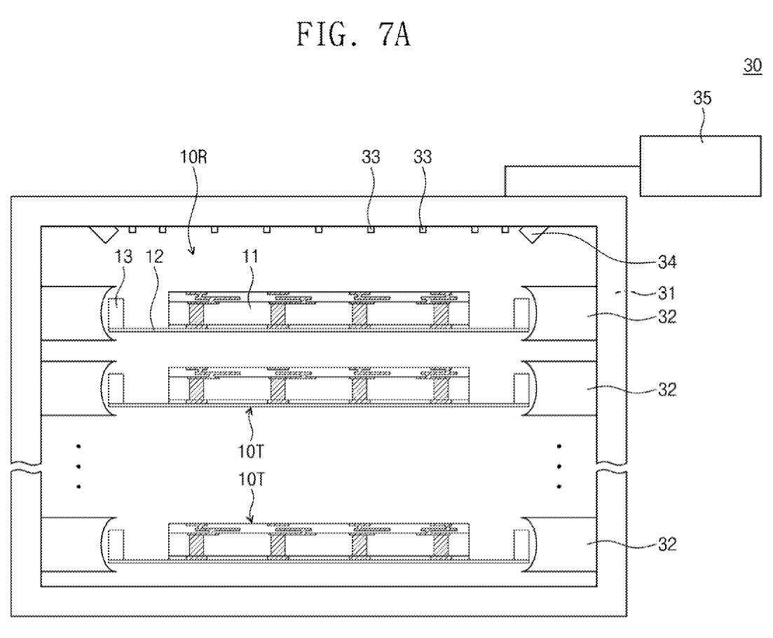

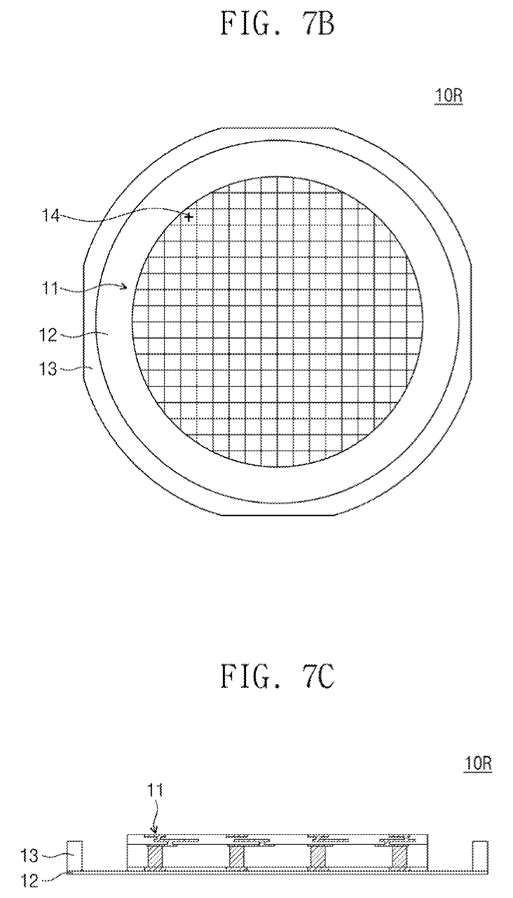

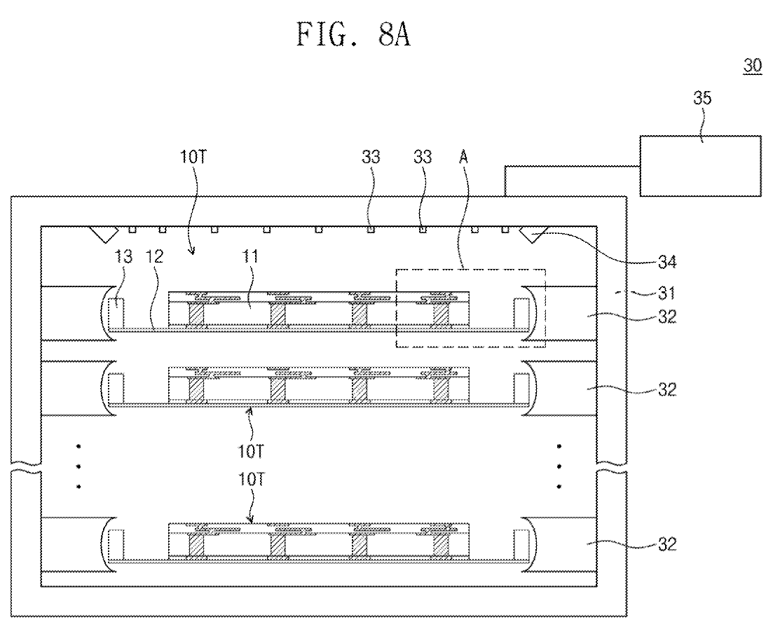

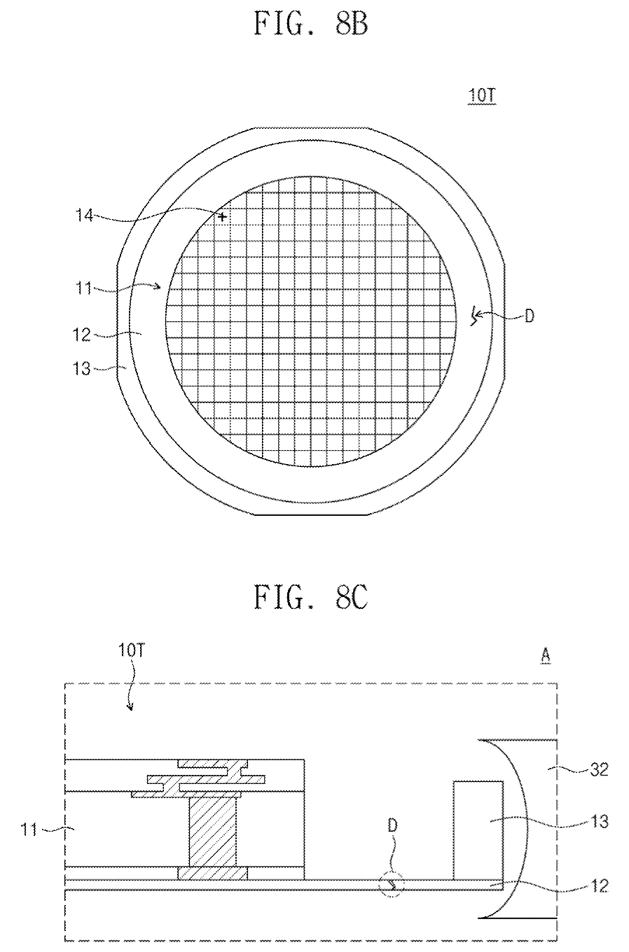

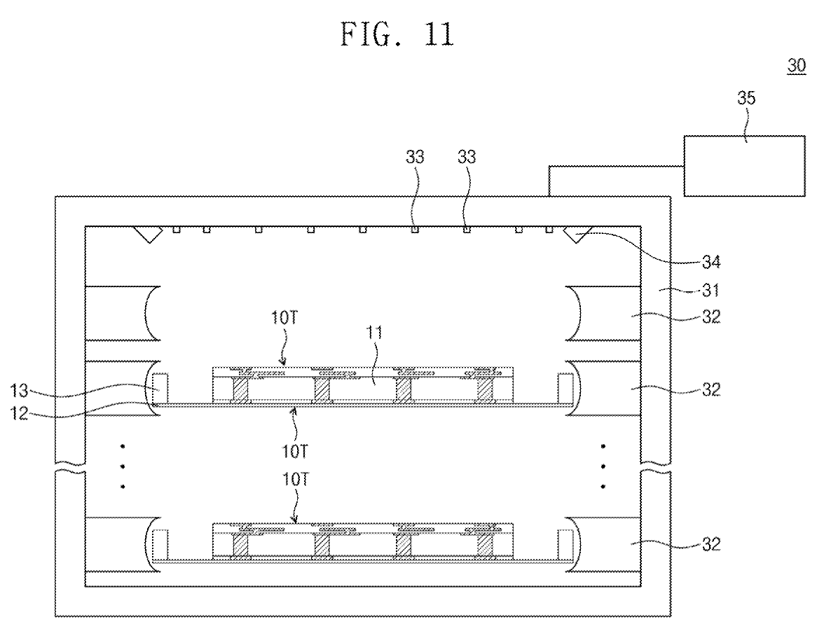

FIG. 6 is a flowchart for describing a method for testing a wafer mounting tape according to one or more embodiments of the present disclosure. FIGS. 7A, 8A, 9A, 10A and 11 are cross-sectional views of an apparatus for testing a wafer mounting tape illustrating a method for testing the wafer mounting tape according to one or more embodiments of the present disclosure. FIG. 7B is a plan view of a reference object illustrating a method for testing a wafer mounting tape according to one or more embodiments of the present disclosure. FIG. 7C is a cross-sectional view of a test object illustrating a method for testing a wafer mounting tape according to one or more embodiments of the present disclosure. FIGS. 8B, 9B, and 10B are top views of a test object illustrating a method for testing a wafer mounting tape according to one or more embodiments of the present disclosure. FIGS. 8C, 9C, 9D, and 10C are partial enlarged views of a cross section of a test object illustrating a method for testing a wafer mounting tape according to one or more embodiments of the present disclosure. FIG. 11 is a cross-sectional view of an apparatus for testing a wafer mounting tape illustrating a method for testing the wafer mounting tape according to one or more embodiments of the present disclosure.

Referring to FIGS. 6, 7A, 7B, and 7C, a reference image may be obtained (S10). The reference image may be obtained using a reference object 10R. Here, the reference object 10R may mean a non-defective good object among objects processed within the substrate processing system. The reference object 10R may be substantially the same as or similar to the test object 10 described with reference to FIGS. 1 and 2. For example, the reference object 10R may include a substrate 11, a wafer mounting tape 12, and a ring frame 13. Hereinafter, the substrate, the wafer mounting tape, and the ring frame of the reference object 10R will be referred to as the reference substrate 11, the reference wafer mounting tape 12, and the reference ring frame 13 for distinguishing from the test object 10. The reference substrate 11 may include a reference wafer. The reference substrate 11 may be attached to the reference wafer mounting tape 12. The reference wafer mounting tape 12 may be adhered or connected to a lower surface of the reference ring frame 13. The reference substrate 11 may be adhered to the reference wafer mounting tape 12. The reference substrate 11 may include a reference key pattern 14 provided on an upper surface thereof. For example, the reference key pattern 14 may include a pattern formed in an intaglio or embossed shape on the upper surface of the reference substrate 11, or a pattern formed of some material layer.

The reference object 10R may be inserted into the wafer mounting tape testing apparatus 30. The reference object 10R may be mounted in a mounting slot 32 of the body 31, for example, a topmost mounting slot 32 among the mounting slots 32.

The second testing unit 34 may photograph an upper portion of the reference object 10R. The reference image may be an image of the reference object 10R photographed by the second testing unit 34. The reference image may include image information on a shape of the upper surface of the reference substrate 11 of the reference object 10R, a shape of an upper surface of the reference wafer mounting tape 12, a shape of a reference ring frame 13, and positions of the reference substrate 11, the reference wafer mounting tape 12, and the reference ring frame 13, and the like. The reference image obtained by the second testing unit 34 may be transmitted to and stored in the image processing unit 35. The reference image may then be used as a comparison reference in the testing of the test object 10T.

Referring to FIGS. 6, 8A, 8B, and 8C, a test object 10T may be prepared (S10). Here, the test object 10T may mean an object to be tested for determination of a failure among the objects processed in the substrate processing system. For convenience of description, the test object 10T described below will be described with reference to the defective test object 10T having a breakage portion D. The test object 10T may be substantially the same as or similar to the test object 10T described with reference to FIGS. 1 and 2. For example, the test object 10T may include a substrate 11, a wafer mounting tape 12, and a ring frame 13. The ring frame 13 may have the attachment region inside. The attachment region may be a region where the substrate 11 is attached to the wafer mounting tape 12 inside the ring frame 13. The wafer mounting tape 12 may be attached to the lower surface of the ring frame 13. The substrate 11 may be attached to the wafer mounting tape 12 within the attachment region. The substrate 11 may include an alignment key pattern 14 provided on an upper surface thereof. For example, the alignment key pattern 14 may include a pattern formed in an intaglio or embossed shape on the upper surface of the substrate 11, or a pattern formed of some material layer.

The breakage portion D may be present in the wafer mounting tape 12 of the test object 10T. For example, the breakage portion D may be a torn portion of the wafer mounting tape 12.

The test object 10T may be inserted into the wafer mounting tape testing apparatus 30. The test object 10T may be mounted on the mounting slot 32 of the body 31, for example, the topmost mounting slot 32 among the mounting slots 32. When a plurality of test objects 10T are provided, each of the test objects 10T may be mounted on one of the mounting slots 32.

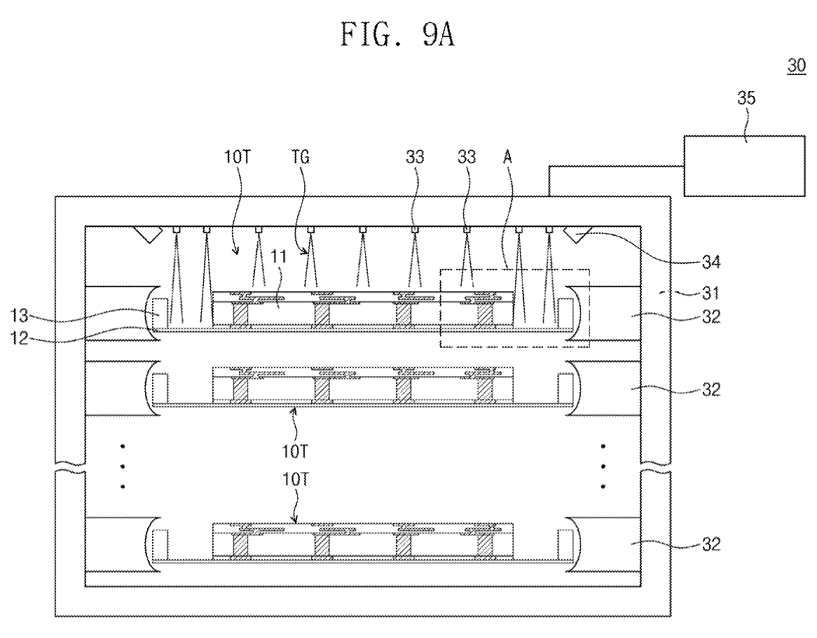

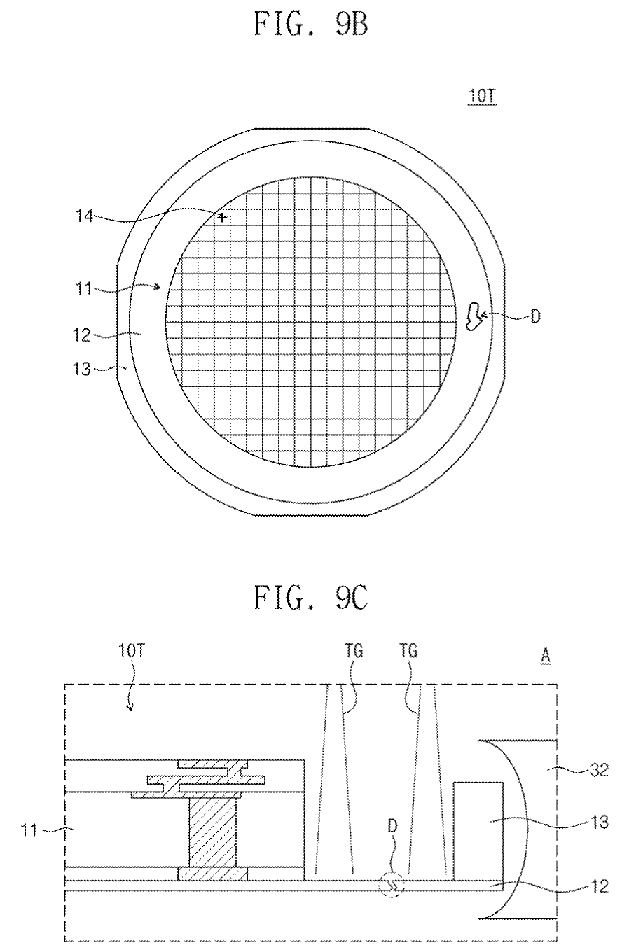

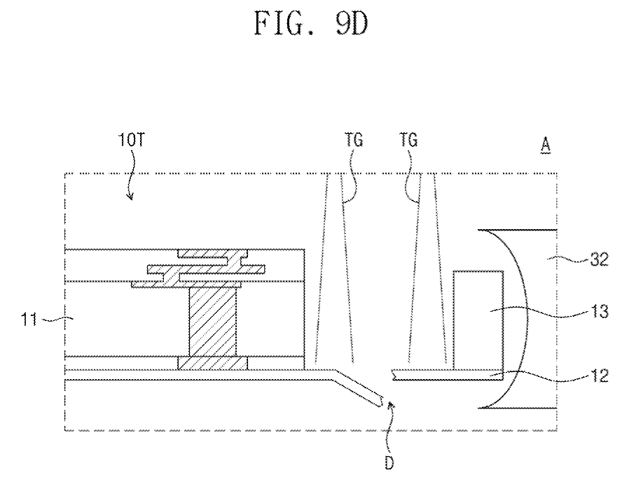

Referring to FIGS. 6, 9A, 9B, and 9C, a testing gas TG may be jetted on the wafer mounting tape 12 and the substrate 11 of the test object 10T using the first testing unit 33 (S30). The testing gas TG may be jetted from above the test object 10T toward an upper surface of the wafer mounting tape 12 and the upper surface of a substrate 11. The breakage portion D of the wafer mounting tape 12 may be expanded by the pressure at which the testing gas TG is jetted. Alternatively, as illustrated in FIG. 9D, a portion of the wafer mounting tape 12 around the breakage portion D may be deformed by the pressure at which the testing gas TG is jetted. Since the testing gas TG is provided as an inert gas, the substrate 11 may not undergo a chemical reaction due to the testing gas TG. That is, the substrate 11 may not be contaminated, deformed, or otherwise negatively affected by the testing gas TG.

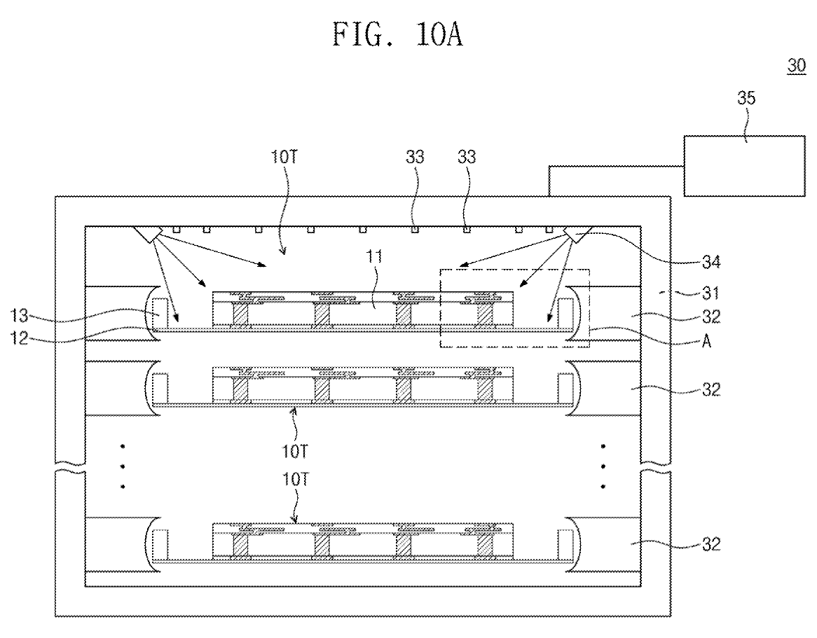

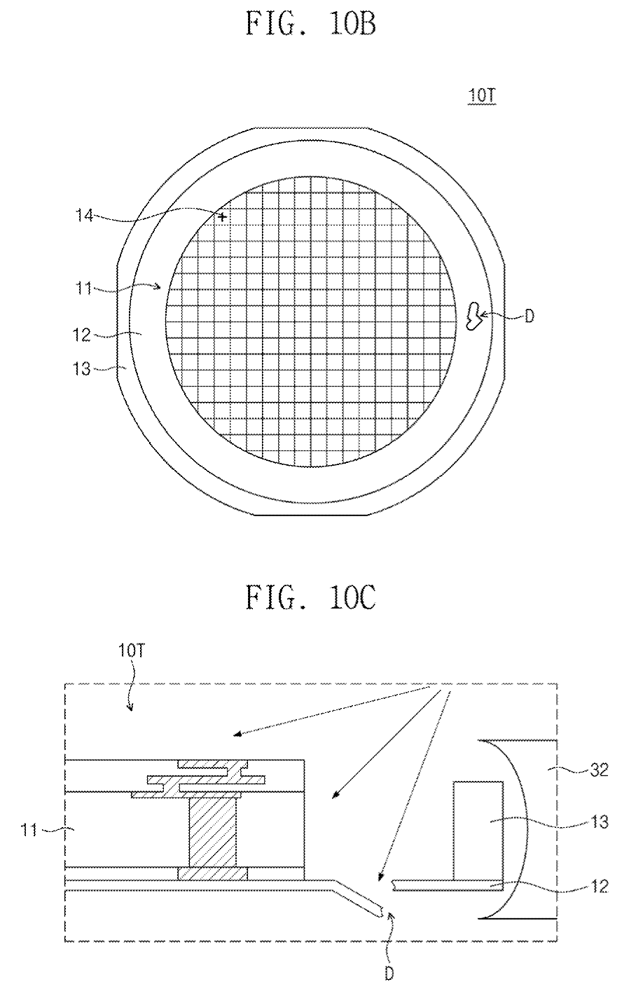

Referring to FIGS. 6, 10A, 10B, and 10C, the ring frame 13, the wafer mounting tape 12, and the substrate 11 of the test object 10T may be photographed using the second testing unit 34 to obtain a testing image (S40). The second testing unit 34 may photograph an upper portion of the test object 10T. The testing image may be an image of the test object 10T photographed by the second testing unit 34. The testing image may include image information on a shape of the upper surface of the substrate 11 of the test object 10T, a shape of the upper surface of the wafer mounting tape 12, a shape of a ring frame 13, positions of the substrate 11, the wafer mounting tapes 12, and the ring frame 13, and the like. When the wafer mounting tape 12 of the test object 10T includes the breakage portion D, the breakage portion D may be recorded in the testing image. The testing image obtained by the second testing unit 34 may be transmitted to and stored in the image processing unit 35.

The step of jetting the testing gas TG on the wafer mounting tapes 12 and the substrates 11 of the test objects 10T described with Reference to FIGS. 9A, 9B, and 9C, and the step of photographing the ring frame 13, the wafer mounting tape 12, and the substrate 11 of the test object 10T described with reference to FIGS. 10A, 10B, and 10C may be sequentially performed in the body 31 of the wafer mounting tape testing apparatus 30.

The testing image may be compared to the reference image (S50). The image processing unit 35 may perform the comparison of the testing image to the reference image. For example, the shape of the upper surface of the wafer mounting tape 12 of the test object 10T recorded in the testing image may be compared with the shape of the upper surface of the reference wafer mounting tape 12 in the reference object 10R recorded in the reference image.

A failure of the wafer mounting tape 12 of the test object 10T may be determined through or based on an error between the testing image and the reference image (S60). For example, a breakage portion D formed on the wafer mounting tape 12 of the test object 10T may cause the error between the testing image and the reference image.

According to embodiments of the present disclosure, before obtaining the testing image using the second testing unit 34, the first testing unit 33 may be used to jet the testing gas TG toward the wafer mounting tape 12 of the test object 10T to expand the breakage portion D. Therefore, the breakage portion D may be more clearly recorded in the testing image, and it may be easier to determine a failure caused by the error between the testing image and the reference image. That is, a method for testing a wafer mounting tape that may prevent missing of a failure determination may be provided.

Furthermore, by using the vision camera that obtains optical information as the second testing unit 34, it is possible to collect not only shape information (for example, a profile or the like) of the test object 10, but also color information when the test object 10 is viewed from above. That is, a more precise testing of the test object 10T may be possible.

An inspection of the breakage portion D formed on the wafer mounting tape 12 of the test object 10T has been described above, but the present invention is not limited thereto.

According to one or more embodiments, the testing image may record the horizontal position of the substrate 11 within the attachment area in the ring frame 13 of the test object 10T.

The testing image may be compared to the reference image (S50). The image processing unit 35 may perform the comparison of the testing image to the reference image. For example, a horizontal position of the substrate 11 and the ring frame 13 of the test object 10T recorded in the testing image may be compared with a horizontal position of the reference substrate 11 and the reference ring frame 13 of the reference object 10R recorded in the reference image.

A failure of the test object 10T may be determined through an error between the testing image and the reference image (S60). For example, a difference between an interval between the ring frame 13 and the substrate 11 of the test object 10T and an interval between the reference ring frame 13 and a reference substrate 11 of the reference object 10R may cause the error between the testing image and the reference image.

According to other embodiments, the testing image may be recorded with a pattern formed on the upper surface of the substrate 11 of the test object 10. For example, the pattern may include a wiring pattern, a pad pattern, or various patterns formed on the upper surface of the substrate 11.

The testing image may be compared to the reference image (S50). The image processing unit 35 may perform the comparison of the testing image to the reference image. For example, a shape of the pattern formed on the upper surface of the substrate 11 of the test object 10T recorded in the testing image may be compared to a shape of a reference pattern formed on the upper surface of the reference substrate 11 of the reference object 10R recorded in the reference image. At this time, the image processing unit 35 may align an image of the substrate 11 of the test object 10T recorded in the testing image with an image of the reference substrate 11 of the reference object 10R recorded in the reference image. For example, the testing image and the reference image may be aligned through the alignment key pattern 14 formed on the substrate 11 of the test object 10T and the reference key pattern 14 formed on the reference substrate 11 of the reference object 10R. Accordingly, the pattern of the substrate 11 of the test object 10T and the reference pattern of the reference substrate 11 of the reference object 10R may be more accurately compared.

A failure of the test object 10T may be determined through an error between the testing image and the reference image (S60). For example, a difference between the shape of the pattern of the substrate 11 of the test object 10T and the shape of the reference pattern of the reference substrate 11 of the reference object 10R may cause the error between the testing image and the reference image.

According to one or more embodiments of the present disclosure, it is possible to simultaneously test whether the wafer mounting tape 12 of the test object 10T is broken, whether the substrate 11 is aligned in the ring frame 13, and whether the pattern of the upper surface of the substrate 11 is defective, through a single testing process. That is, the present disclosure may provide a more simplified method for testing a wafer mounting tape.

Referring to FIG. 11, the test object 10 determined to be defective may be exported out from the wafer mounting tape testing apparatus 30 and transferred to the previous process of the substrate processing system. When the test object 10 is determined to be a good product, the test object 10 may be exported out from the wafer mounting tape testing apparatus and transferred to a post-process of the substrate processing system. Accordingly, the topmost mounting slot 32 of the body 31 of the wafer mounting tape testing apparatus 30 may be empty.

Subsequently, the testing process may be continuously performed on the test object 10 mounted on a mounting slot 32 below the topmost mounting slot 32 of the body 31 of the wafer mounting tape testing apparatus 30. The testing process may be the same as or similar to the process described with reference to FIG. 6.

According to one or more embodiments of the present disclosure, the wafer mounting tape testing apparatus 30 may include vertically arranged mounting slots 32, and the first testing unit 33 and the second testing unit 34 may be located above the mounting slots 32. Therefore, it may be easy to continuously test the plurality of test objects 10.

The apparatus for testing a wafer mounting tape according to embodiments of the present disclosure may test the objects of the substrate processing system, and also, serve as a buffer unit for temporarily storing the objects between a plurality of unit processes of the substrate processing system. Thus, the apparatus for testing and storage of the objects may be provided as one, not separately. That is, the wafer mounting tape testing apparatus may provide the substrate processing system with more simplified process steps.

Further, the wafer mounting tape testing may have vertically arranged the mounting slots, and may be easy to continuously test a plurality of test objects.

The method for testing a wafer mounting tape according to the embodiments of the present disclosure may jet the testing gas toward the wafer mounting tape expand the breakage portion before obtaining the testing image. Therefore, the breakage portion may be more clearly recorded in the testing image, and it may be easier to determine the failure caused by the error between the testing image and the reference image. That is, the present disclosure may provide a more accurate method for testing a wafer mounting tape that detects and identifies failures or defects in the wafer mounting tape 12 with improved reliability and consistency.

Furthermore, by using the vision camera that obtains optical information as the second testing unit, it is possible to collect not only shape information of the test object, but also color information when the test object is viewed from above. That is, a more precise testing of the test object may be possible.

In addition, through a single testing process, it is possible to simultaneously test whether the wafer mounting tape is broken, whether the substrate is aligned in the ring frame, and whether the pattern on the upper surface of the substrate is defective. That is, the present disclosure may provide a more simplified method for testing a wafer mounting tape.

While embodiments are described above, a person skilled in the art may understand that many modifications and variations are made without departing from the spirit and scope of the present disclosure defined in the following claims. Accordingly, the example embodiments of the present disclosure should be considered in all respects as illustrative and not restrictive, with the spirit and scope of the present disclosure being indicated by the appended claims.

What is claimed is:

1. A method for testing wafer mounting tape comprising:
attaching a wafer mounting tape to a lower surface of a ring frame, the ring frame having a wafer attachment region inside thereof;
attaching a wafer to the wafer mounting tape within the wafer attachment region;
jetting a testing gas on the wafer mounting tape and the wafer using a first testing device;
obtaining a testing image of the ring frame, the wafer mounting tape, and the wafer using a second testing device;
comparing the testing image to a reference image; and
determining a failure of the wafer mounting tape based on an error between the testing image and the reference image.

2. The method of claim 1, wherein a breakage portion formed in the wafer mounting tape is configured to expand due to the jetting the testing gas.

3. The method of claim 2, wherein the breakage portion is recorded in the testing image, and
wherein the breakage portion is configured to cause the error between the testing image and the reference image.

4. The method of claim 1, wherein the testing gas comprises an inert gas.

5. The method of claim 1, wherein the first testing device is above the ring frame, the wafer mounting tape, and the wafer; and
wherein the testing gas is jetted from above the ring frame, the wafer mounting tape, and the wafer towards the ring frame, the wafer mounting tape, and the wafer.

6. The method of claim 1, wherein the first testing device includes a plurality of gas jetting nozzles.

7. The method of claim 1, wherein a horizontal position of the wafer within the wafer attachment region is recorded in the testing image, and
wherein an interval between the ring frame and the wafer causes the error between the testing image and the reference image.

8. The method of claim 1, wherein the second testing device includes at least one camera.

9. The method of claim 1, further comprising:
comparing an upper surface of the wafer recorded in the testing image with an upper surface of a reference wafer recorded in the reference image to determine a failure of a pattern on the upper surface of the wafer.

10. The method of claim 9, wherein the wafer includes an alignment key pattern on the upper surface of the wafer, and
wherein the method further comprises aligning the testing image and the reference image with respect to the alignment key pattern before the comparing the upper surface of the wafer with the upper surface of the reference wafer.

11. The method of claim 1, further comprising:
moving the ring frame, the wafer mounting tape, and the wafer into a testing apparatus before the jetting the testing gas,
wherein the testing apparatus includes a body comprising an inner space, the first testing device in the inner space, and the second testing device in the inner space, and
wherein the jetting the testing gas and the obtaining the testing image are performed sequentially in the testing apparatus.

12. An apparatus for testing wafer mounting tape comprising:
a body comprising an inner space configured to receive one or more test objects;
a mounting slot in the inner space;
a first testing device in the inner space and above the one or more test objects, wherein the first testing device is configured to expand a breakage portion of a wafer mounting tape of the one or more test objects by jetting a testing gas toward the one or more test objects; and
a second testing device in the inner space and above the one or more test objects, wherein the second testing device is configured to monitor a planar shape of the one or more test objects.

13. The apparatus of claim 12, wherein the mounting slot comprises a plurality of mounting slots,
wherein the plurality of mounting slots are arranged vertically in the inner space, and
wherein each of the plurality of mounting slots comprises, respectively, a space for mounting the one or more test objects.

14. The apparatus of claim 12, wherein the first testing device comprises a plurality of gas jetting nozzles on the mounting slot in the inner space.

15. The apparatus of claim 12, wherein the testing gas comprises an inert gas.

16. The apparatus of claim 12, wherein the second testing device comprises at least one camera on the mounting slot in the inner space.

17. The apparatus of claim 12, further comprising an image processing device,
wherein the image processing device is configured to compare a testing image taken by the second testing device with a reference image.

18. A method for testing wafer mounting tape comprising:
obtaining a reference image of a reference wafer mounting tape using a first testing device;
jetting a testing gas toward a wafer mounting tape using a second testing device, wherein a breakage portion formed in the wafer mounting tape is configured to expand due to the jetting the testing gas;
obtaining a testing image of the wafer mounting tape using the first testing device;
comparing the testing image to the reference image; and
determining a failure of the wafer mounting tape based on an error between the testing image and the reference image,
wherein the breakage portion is recorded in the testing image, and
wherein the breakage portion is configured to cause the error between the testing image and the reference image.

19. The method of claim 18, further comprising:
attaching a wafer on the wafer mounting tape before the jetting the testing gas;
jetting, using the second testing device, the testing gas toward the wafer mounting tape and the wafer; and
comparing an upper surface of the wafer recorded in the testing image with an upper surface of a reference wafer recorded in the reference image to determine a failure of a pattern on the upper surface of the wafer.

20. The method of claim 18, wherein the first testing device includes at least one camera.
